(19) United States
(12) Patent Application Publication
(10) Pub. No.: US 2025/0054925 A1
(43) Pub. Date: Feb. 13, 2025

(54) SEMICONDUCTOR PACAKGE AND METHOD FOR FORMING THE SAME

(71) Applicant: STATS ChipPAC Pte. Ltd., Singapore (SG)

(72) Inventors: YongHyuk JEONG, Incheon (KR); DaAe LEE, Incheon (KR); EunByeol SON, Gyeong-gi (KR)

(21) Appl. No.: 18/749,657

(22) Filed: Jun. 21, 2024

(30) Foreign Application Priority Data
Aug. 9, 2023 (CN) 202310997365.5

(51) Int. Cl. H01L 25/10; H01L 23/00; H01L 23/31; H01L 23/36; H01L 23/498; H01L 23/538; H01L 25/00; H01L 25/065

(52) U.S. Cl. CPC H01L 25/105; H01L 23/3157; H01L 23/36; H01L 23/5383; H01L 24/16; H01L 25/0655; H01L 25/50; H01L 23/49816; H01L 2224/16235; H01L 2225/1011

(57) ABSTRACT

A semiconductor package is provided, comprising: a package substrate; a first plurality of semiconductor dice disposed on a front side of the package substrate; an embedded sub-package disposed on a back side of the package substrate, comprising: a sub-package substrate, wherein a front side of the sub-package substrate is attached to the back side of the package substrate; an interconnection layer attached to a back side of the sub-package substrate, comprising a second plurality of vertical interconnection portions and at least one horizontal interconnection portion; and a second plurality of semiconductor dice disposed on the back side of the sub-package substrate through the interconnection layer; and a first plurality of vertical interconnection portions disposed on the back side of the package substrate; and solder bumps attached to the first plurality of vertical interconnection portions.

### TECHNICAL FIELD

The present application generally relates to semiconductor devices and more particularly, to a semiconductor package with embedded semiconductor packages.

### BACKGROUND OF THE INVENTION

The semiconductor industry is constantly faced with complex integration challenges as consumers want their electronics to be smaller, faster and higher performance with more and more functionalities packed into a single device. In order to meet the needs of the consumers, more and more electronic components are integrated together at a higher density. Yet, the structure of a semiconductor package is rather complicated, and its manufacturing process may have limited efficiency.

Therefore, a need exists for a method for forming a semiconductor package with improved manufacturing efficiency.

### SUMMARY OF THE INVENTION

An objective of the present application is to provide a semiconductor package with improved manufacturing efficiency.

According to an aspect of the present application, a semiconductor package is provided. The semiconductor package includes: a package substrate having a front side and a back side; a first plurality of semiconductor dice disposed on the front side of the package substrate and electrically coupled to the package substrate; an embedded sub-package disposed on the back side of the package substrate, the embedded sub-package including: a sub-package substrate having a front side and a back side, wherein the front side of the sub-package substrate is attached to the back side of the package substrate and electrically coupled to the package substrate; an interconnection layer attached to the back side of the sub-package substrate and electrically coupled to the sub-package substrate; wherein the interconnection layer includes a second plurality of vertical interconnection portions and at least one horizontal interconnection portion; and a second plurality of semiconductor dice disposed on the back side of the sub-package substrate through the interconnection layer, wherein each of the second plurality of semiconductor dice is electrically coupled to the sub-package substrate through at least one of the second plurality of vertical interconnection portions, and at least two of the second plurality of semiconductor dice are further electrically coupled to each other through the at least one horizontal interconnection portion, such that the first plurality of semiconductor dice are electrically coupled to each other through the embedded sub-package; and a first plurality of vertical interconnection portions disposed on the back side of the package substrate and in parallel with the embedded sub-package, wherein each of the first plurality of semiconductor dice is electrically coupled to one of the first plurality of vertical interconnection portions; and solder bumps attached to the first plurality of vertical interconnection portions.

According to an aspect of embodiments of the present application, a method for forming a semiconductor package is provided. The method may include: providing a first plurality of semiconductor dice and a second plurality of semiconductor dice; forming an embedded sub-package, comprising: forming a second plurality of vertical interconnection portions on and electrically coupled to the second plurality of semiconductor dice; attaching at least one horizontal interconnection portion on the second plurality of semiconductor dice, wherein at least two of the second plurality of semiconductor dice are electrically connected to each other via the at least one horizontal interconnection portion; molding the second plurality of semiconductor dice, the second plurality of vertical interconnection portions and the at least one horizontal interconnection portion; forming a sub-package substrate on the second plurality of semiconductor dice, the second plurality of vertical interconnection portions and the at least one horizontal interconnection portion, wherein the second plurality of vertical interconnection portions is electrically coupled to the sub-package substrate, wherein each of the second plurality of semiconductor dice is electrically coupled to the sub-package substrate through at least one of the second plurality of vertical interconnection portions; forming a first plurality of vertical interconnection portions; molding the embedded sub-package and the first plurality of vertical interconnection portions, wherein the first plurality of vertical interconnection portions is in parallel with the embedded sub-package; attaching solder bumps, such that the solder bumps are electrically coupled to the first plurality of vertical interconnection portions; forming a package substrate on the embedded sub-package and the first plurality of vertical interconnection portions, wherein the package substrate comprises a front side and a back side, wherein the first plurality of vertical interconnection portions and the sub-package substrate of the embedded sub-package substrate are attached to and electrically coupled to the back side of the package substrate; disposing the first plurality of semiconductor dice on the front side of the package substrate, wherein the first plurality of semiconductor dice is electrically coupled to the package substrate, wherein the first plurality of semiconductor dice is electrically coupled to each other through the embedded sub-package, wherein each of the first plurality of semiconductor dice is electrically coupled to one of the first plurality of vertical interconnection portions.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of a semiconductor package according to an embodiment of the present application.

FIGS. 2A to 2F illustrate cross-sectional views of a method for forming an embedded sub-package according to an embodiment of the present application.

FIGS. 3A to 3E illustrate cross-sectional views of a method for forming a vertical interconnection portion according to an embodiment of the present application.

FIGS. 4A to 4C illustrate cross-sectional views of portions of a method for forming a vertical interconnection portion according to another embodiment of the present application.

FIGS. 5A to 5G illustrate cross-sectional views of a method for forming a semiconductor package according to an embodiment of the present application.

FIGS. 6 to 7 illustrate cross-sectional views of semiconductor packages according to two embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

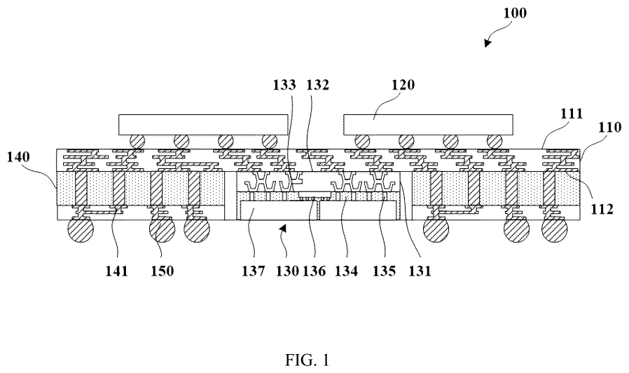

Referring to FIG. 1, a semiconductor package 100 according to an embodiment of the present application is shown. The semiconductor package 100 includes a package substrate 110 having a front side 111 and a back side 112. A first plurality of semiconductor dice 120 is disposed on the front side 111 of the package substrate 110 and electrically coupled to the package substrate 110. Some other components of the semiconductor package 100 may be disposed on the back side 112 of the package substrate 110, which will be elaborated below.

The package substrate 110 achieves electrical connection between the first plurality of semiconductor dice 120 on its front side 111 and components its back side 112. In some embodiments, the package substrate 110 includes one or more insulating layers interleaved with one or more conductive layers. Insulating layer may be a core insulating board in one embodiment, with conductive layers patterned over the top and bottom surfaces, e.g., a copper-clad laminate substrate. Conductive layers also include conductive vias electrically coupled through insulating layers. The package substrate 110 can include any number of conductive and insulating layers interleaved over each other.

Still referring to FIG. 1, on the back side 112 of the package substrate 110, an embedded sub-package 130 and a first plurality of vertical interconnection portions 140 are disposed. Specifically, the embedded sub-package 130 includes a sub-package substrate 131, an interconnection layer 134 and a second plurality of semiconductor dice 137. Preferably, the sub-package substrate 131, the interconnection layer 134 and the second plurality of semiconductor dice 137 are disposed from top to bottom and electrically coupled together.

Specifically, the sub-package substrate 131 has a front side 132 and a back side 133, the front side 132 of the sub-package substrate 131 is attached to the back side 112 of the package substrate 110 and electrically coupled to the package substrate 110. In some embodiments, the sub-package substrate 131 may include similar insulating layers and conductive layers therein as the package substrate 110. In some embodiments, the sub-package substrate 131 includes dielectric layers and conductive layers therein. The sub-package substrate 131 achieves redistribution from the above package substrate 110 to the interconnection layer 134, especially to the second plurality of vertical interconnection portions 135 below.

The interconnection layer 134 is attached to the back side 133 of the sub-package substrate 131 and electrically coupled to the sub-package substrate 131. The interconnection layer 134 includes a second plurality of vertical interconnection portions 135 and at least one horizontal interconnection portion 136. In some embodiments, the second plurality of vertical interconnection portions 135 includes a conductive layer 135 electrically coupled to the second plurality of semiconductor dice 137 below. In some embodiments, the at least one horizontal interconnection portion 136 is a silicon bridge with terminals or pads. The terminals or pads may include solder, copper or gold interconnections. In some embodiments, the terminals may have a fine interconnect pitch between 0.1 um to 1 um. The at least one horizontal interconnection portion 136 may electrically couple at least two of the second plurality of semiconductor dice 137 below together. Preferably, the second plurality of vertical interconnection portions 135 may surround the at least one horizontal interconnection portion 136 in the interconnection layer 134.

Still referring to FIG. 1, the second plurality of semiconductor dice 137 are disposed on the back side 133 of the sub-package substrate 131 through the interconnection layer 134. Specifically, each of the second plurality of semiconductor dice 137 is electrically coupled to the sub-package substrate 131 through at least one of the second plurality of vertical interconnection portions 135.

It can be seen that, the embedded sub-package 130 achieves integrated electrical connection therein. Components external to the embedded sub-package 130 may achieve electrical connection via the embedded sub-package 130 itself, instead of requiring other electrical routing. Electrical connections in-between the first plurality of semiconductor dice 120 and the second plurality of semiconductor dice 137 of the embedded sub-package 130 are achieved. Specifically, the first plurality of semiconductor dice 120 are electrically coupled to each other through the embedded sub-package 130.

Still referring to FIG. 1, as mentioned above, the semiconductor package 100 also includes the first plurality of vertical interconnection portions 140 on the back side 112 of the package substrate 110. In general, the first plurality of vertical interconnection portions 140 is in parallel with the embedded sub-package 130. Through the package substrate 110, each of the first plurality of semiconductor dice 120 is electrically coupled to one of the first plurality of vertical interconnection portions 140. Therefore, each of the first plurality of vertical interconnection portions 140 achieves redistribution for at least a portion of the corresponding semiconductor die. It can be understood that the first plurality of vertical interconnection portions 140 may further include redistribution structures 141 for electrically connecting them to other components below. In some embodiments, the first plurality of vertical interconnection portions 140 may also function as providing mechanical support for the semiconductor package 100.

In some embodiments, each of the first plurality of vertical interconnection portions 140 may include at least one conductive via or at least one conductive pillar. The first plurality of vertical interconnection portions 140 may be molded with a polymer composite material, such as epoxy resin, epoxy acrylate, or any suitable polymer with or without filler, with conductive vias or pillars passing through the polymer composite material.

Further, solder bumps 150 are attached to the first plurality of vertical interconnection portions 140, such that the above-mentioned semiconductor package 100 may be further attached to another circuit board or substrate for integration with other components.

As mentioned above, electrical interconnection is achieved by the embedded sub-package 130. Specifically, the at least one horizontal interconnection portion 136 may function as a center of the electrical interconnection. Therefore, heat may be generated and accumulated significantly in the semiconductor package 100, which requires dissipation for optimal performance. In some embodiments, an interconnection portion heat spreader (not shown) may be disposed for the at least one horizontal interconnection portion 136. Specifically, the interconnection portion heat spreader may be in thermal contact with the at least one horizontal interconnection portion 136. It can be understood that, in some embodiments, the interconnection portion heat spreader may include thermal conductive vias embedded in the sub-package substrate 131 and the package substrate 110. The interconnection portion heat spreader may also extend above the package substrate 110 for further heat dissipation.

As illustrated above, the embedded sub-package 130 includes components that may be integrated beforehand, that is, it may be modularly preformed before being assembled with other components. Similarly, the first plurality of vertical interconnection portions 140 may also be modularly preformed. The semiconductor package 100 achieves high integration of multiple semiconductor dice, achieves fast electrical connection between the multiple semiconductor dice with the at least one horizontal interconnection portion as a bridge portion, and also achieves the modularization of package components, which benefits customizing specification and size. Therefore, the manufacturing efficiency of the semiconductor package 100 can be improved, and the semiconductor package structure is convenient for adaptation.

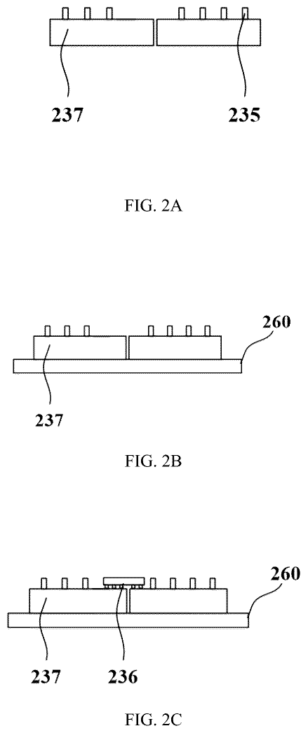

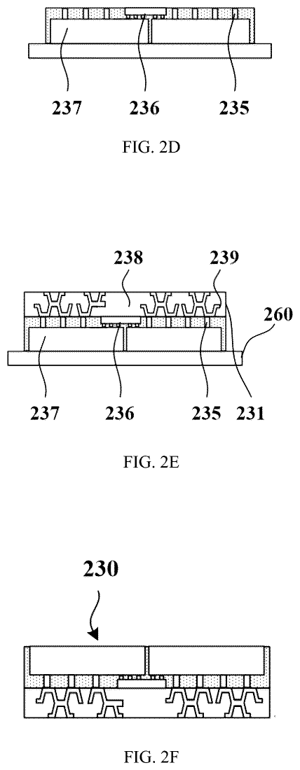

FIGS. 2A to 2F illustrate cross-sectional views of a method for forming an embedded sub-package according to an embodiment of the present application.

Referring to FIG. 2A, a plurality of semiconductor dice 237 is provided. Also, a plurality of vertical interconnection portions 235 is formed on the plurality of semiconductor dice 237. In some embodiments, the plurality of vertical interconnection portions 235 may include a conductive layer.

Referring to FIG. 2B, the plurality of semiconductor dice 237 is attached on a carrier 260. In some embodiments, the carrier 260 contains a base material such as silicon, polymer, polymer composite, metal foil, ceramic, glass, glass epoxy, beryllium oxide, tape, or other suitable low-cost, rigid material for structural support. The carrier 260 may be wafer-shaped or circular with a diameter of 15-30 centimeters (cm), for example. An adhesive film or layer may be formed over the carrier 260. The adhesive layer can be a flexible plastic base film, such as polyvinyl chloride (PVC) or polyolefin, with a synthetic acrylic adhesive or ultraviolet (UV)-sensitive adhesive, for device mounting and removal. Adhesive layer may be releasable by light, heat, laser, or mechanical pressure. Alternatively, an adhesive material such as thermal epoxy, polymer composite or inorganic bonding compounds, can be applied to the carrier 260.

Referring to FIG. 2C, at least one horizontal interconnection portion 236 is attached on the plurality of semiconductor dice 237. As illustrated above, at least two of the plurality of semiconductor dice 237 are electrically connected to each other via the at least one horizontal interconnection portion 236. For example, the horizontal interconnection portion 236 can be attached on the semiconductor dice 237 using a bonding process or a surface mounting process.

Referring to FIG. 2D, the plurality of semiconductor dice 237, the plurality of vertical interconnection portions 235 and the at least one horizontal interconnection portion 236 are molded. In some embodiments, a molding compound may be deposited to cover the plurality of semiconductor dice 237, the plurality of vertical interconnection portions 235 and the at least one horizontal interconnection portion 236 using paste printing, compressive molding, transfer molding, liquid encapsulant molding, vacuum lamination, spin coating, or another suitable process. The molding compound can be a polymer composite material, such as epoxy resin, epoxy acrylate, or any suitable polymer with or without filler. The molding compound is non-conductive, and provides structural support for the other components. It can be appreciated that the molding compound is preferably formed around the edges of the semiconductor dice 237 to provide isolation from their respective lateral sides.

Referring to FIG. 2E, a sub-package substrate 231 is formed on the plurality of semiconductor dice 237, the plurality of vertical interconnection portions 235 and the at least one horizontal interconnection portion 236. In some embodiments, the sub-package substrate 231 includes a dielectric layer 238 and a conductive layer 239. As shown in FIG. 2E, the plurality of vertical interconnection portions 235 is electrically coupled to the sub-package substrate 231, wherein each of the plurality of semiconductor dice 237 is electrically coupled to the sub-package substrate 231 through at least one of the plurality of vertical interconnection portions 235.

Next, referring to FIG. 2F, the carrier is removed, therefore the embedded sub-package 230 is formed, which may be used in a subsequent process to integrate it with other components of a semiconductor package.

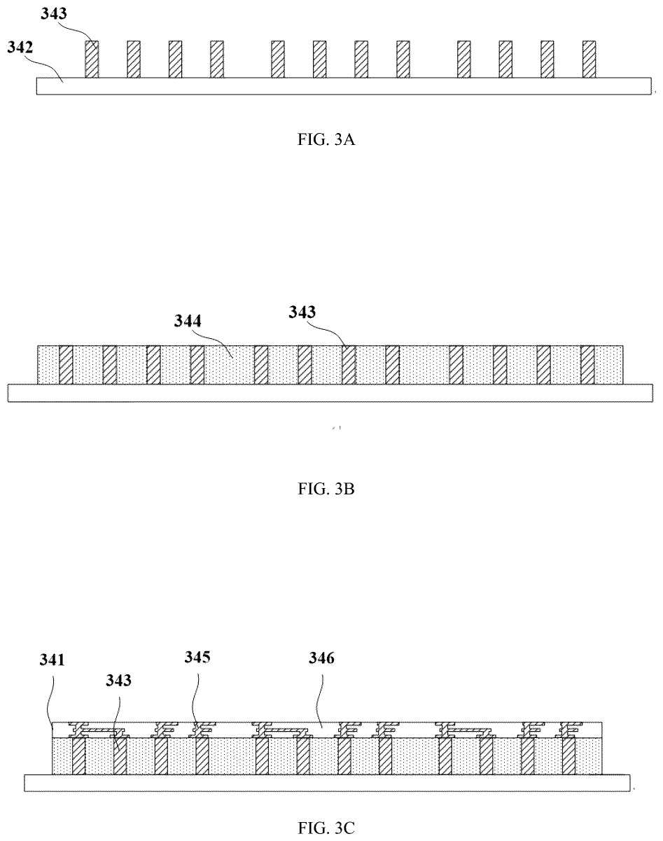

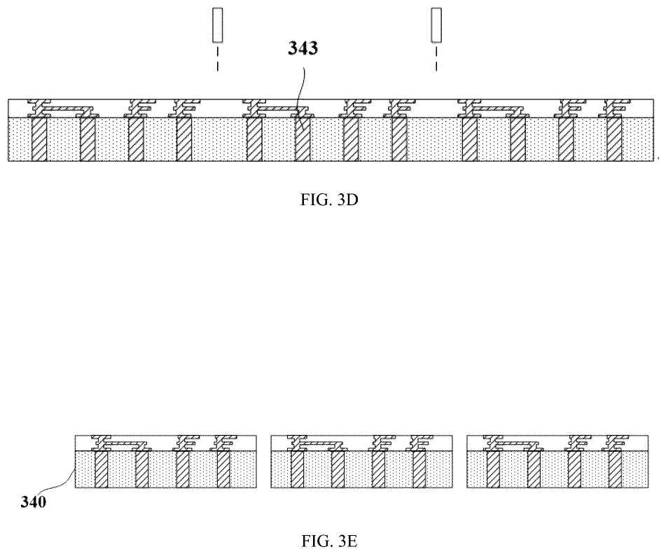

FIGS. 3A to 3E illustrate cross-sectional views of a method for forming a vertical interconnection portion according to an embodiment of the present application.

Referring to FIG. 3A, multiple conductive pillars 343 are provided on a carrier 342. Preferably, the multiple conductive pillars 343 may include Cu, Al, Sn, Ni, Au, Ag, Pb, Bi, etc. or a combination thereof. In some embodiments, the multiple conductive pillars 343 may be implemented as stacked bumps or stud bumps. It can be understood that, the number of the multiple conductive pillars 343 should be enough for forming a plurality of vertical interconnection portions.

Referring to FIG. 3B, the multiple conductive pillars 343 are molded with a molding material 344. In order to achieve further electrical connection, the conductive pillars 343 may be exposed from the molding material 344. For example, grinding may be performed after molding process to expose the conductive pillars 343. The molding material may be a polymer composite material or any other suitable materials.

Next, referring to FIG. 3C, a redistribution layer 341 is formed on the molded conductive pillars 343. Specifically, the redistribution layer 341 may include a conductive layer 345 and a dielectric layer 346. In this way, the multiple conductive pillars 343 are electrically connected to the redistribution layer 341.

Referring to FIG. 3D, singulation is performed to the multiple conductive pillars 343 to obtain each vertical interconnection portion 340 of a plurality of vertical interconnection portions as shown in FIG. 3E. For example, singulation may be performed by cutting at a predefined dicing channel with a saw or a laser cutting tool. These vertical interconnection portions may have the same shape, size or layout, or may have different shapes, sizes or layouts, depending on the components they are connecting.

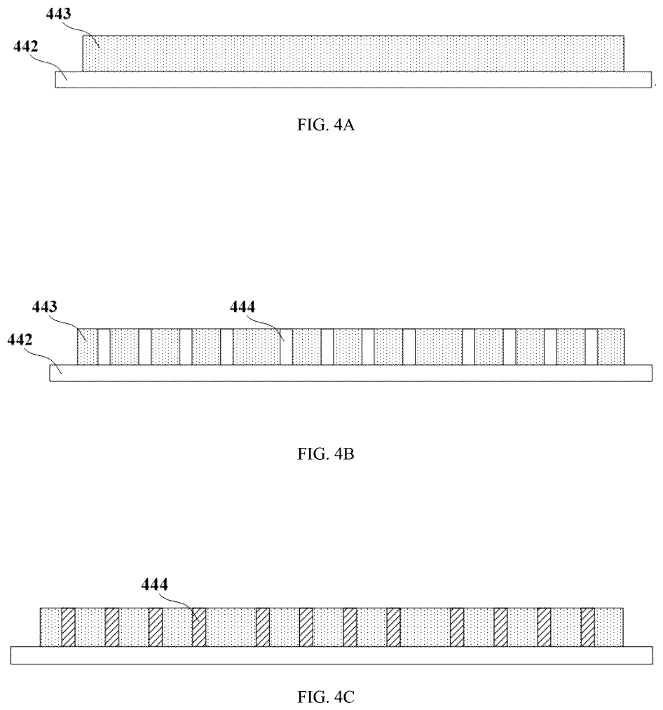

In some other embodiments, the plurality of vertical interconnection portions may be formed in another manner as illustrated below with reference to FIGS. 4A to 4C.

Referring to FIG. 4A, a dielectric layer 443 is formed on a carrier 442. Then, as shown in FIG. 4B, multiple through-holes 444 are formed in the dielectric layer 443. In some embodiments, multiple through-holes 444 may be formed using laser or etching. Referring to FIG. 4C, a conductive material is filled in the multiple vias to form multiple conductive vias where the through-holes are.

After the steps shown in FIG. 4A-4C, steps shown in FIGS. 3C to 3E may be subsequently performed to obtain the plurality of vertical interconnection portions. These following steps are not repeated herein.

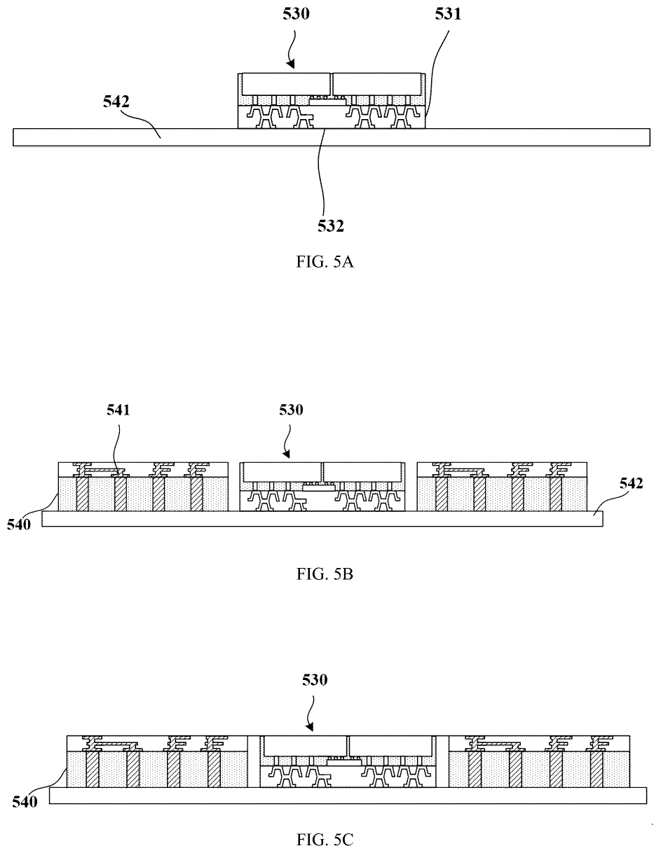

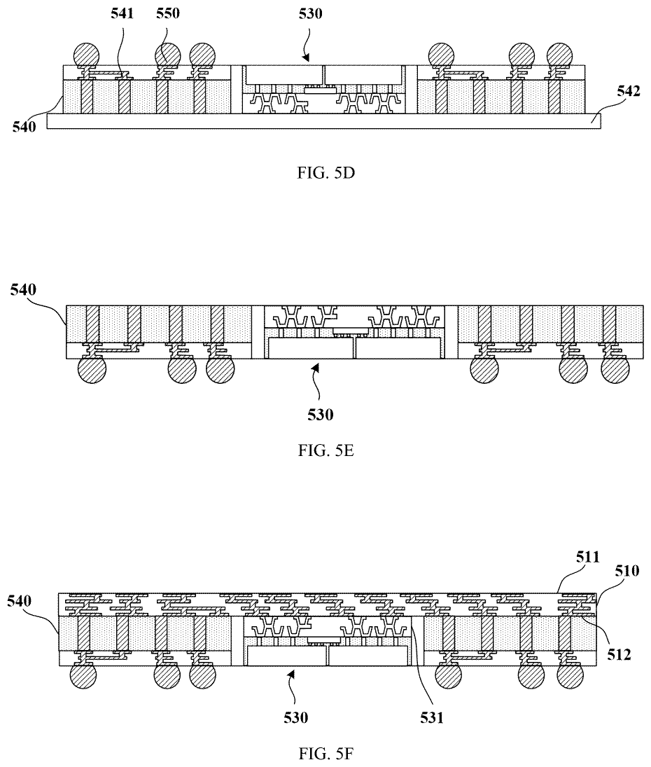

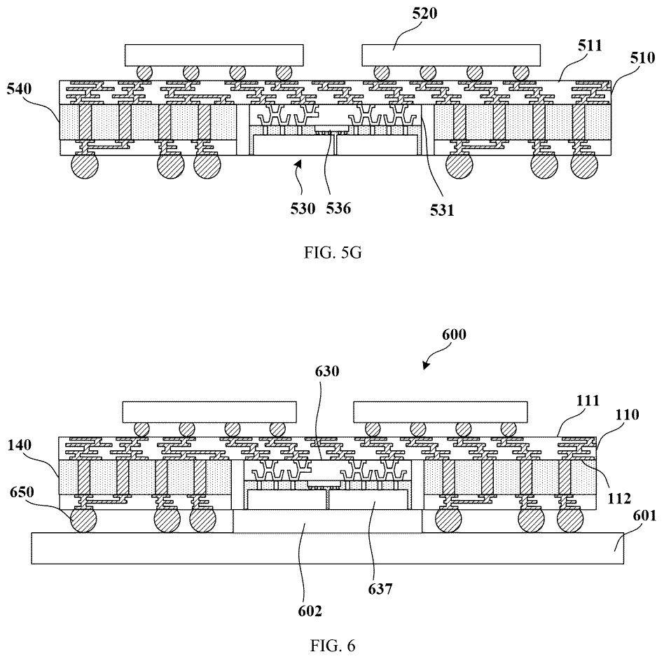

FIGS. 5A to 5G illustrate cross-sectional views of a method for forming a semiconductor package according to an embodiment of the present application.

Referring to FIG. 5A, a preformed embedded sub-package 530 is attached on a carrier 542, wherein a front side 532 of a sub-package substrate 531 is attached to the carrier 542.

Referring to FIG. 5B, a plurality of vertical interconnection portions 540 is also attached to the carrier 542. In some embodiments, the plurality of vertical interconnection portions 540 includes a redistribution layer 541, and the redistribution layer 541 faces away from the carrier 542.

Referring to FIG. 5C, the embedded sub-package 530 and the plurality of vertical interconnection portions 540 are molded together using a molding process, wherein the first plurality of vertical interconnection portions 540 is in parallel with the embedded sub-package 530. In other words, the vertical interconnection portions 540 and the embedded sub-package 530 do not overlap with each other. In some embodiments, after the molding process, conductive structures of the redistribution layer 541 can be exposed from the molding material to be further formed with electrical connections such as solder bumps.

Referring to FIG. 5D, solder bumps 550 are attached using such as a surface mounting process, such that the solder bumps 550 are electrically coupled to the plurality of vertical interconnection portions 540. In some embodiments, the solder bumps 550 are electrically coupled to the redistribution layer 541 to be electrically coupled to the plurality of vertical interconnection portions 540. It can be understood that, solder bumps 550 may also be attached at other time points, such as after chip attach as shown in FIG. 5G as illustrated in the paragraph below.

Next, referring to FIG. 5E, the carrier 542 is removed. In some embodiments, the entire package structure may be flipped over to facilitate further attachment of the package substrate on the plurality of vertical interconnection portions 540 and the embedded sub-package 530 after the molding process.

Referring to FIG. 5F, a package substrate 510 is formed on the embedded sub-package 530 and the plurality of vertical interconnection portions 540. The package substrate 510 includes a front side 511 and a back side 512. The plurality of vertical interconnection portions 540 and the sub-package substrate 531 of the embedded sub-package 530 are attached to and electrically coupled to the back side 512 of the package substrate 510.

Referring to FIG. 5G, a plurality of semiconductor dice 520 is disposed on the front side 511 of the package substrate 510, wherein the plurality of semiconductor dice 520 is electrically coupled to the package substrate 510. In this way, the plurality of semiconductor dice 520 is electrically coupled to each other through the embedded sub-package 530. Also, each of the plurality of semiconductor dice 520 is electrically coupled to one of the plurality of vertical interconnection portions 540. It can be understood that, in some embodiments, solder bumps 550 may be attached after the attachment of the plurality of semiconductor dice 520.

As mentioned above, the at least one horizontal interconnection portion 536 may function as a center of electrical interconnection and may generate heat that requires dissipation for optimal performance. In some embodiments, an interconnection portion heat spreader (not shown) may be formed, which is in thermal contact with the at least one horizontal interconnection portion 536. In some embodiments, thermal conductive vias may be formed which are embedded in the sub-package substrate 531 and the package substrate 510. The interconnection portion heat spreader may also extend above the package substrate 510 for further heat dissipation.

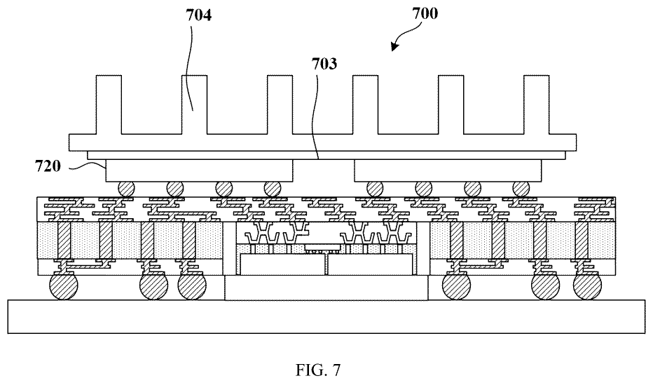

FIGS. 6 to 7 illustrate cross-sectional views of semiconductor packages according to two embodiments of the present application respectively.

Referring to FIG. 6, a semiconductor package 600 may include means for further heat dissipation. In particular, the semiconductor package 600 further includes a base board 601, on which solder bumps 650 are attached. Also, a base thermal interface material layer 602 is formed beneath an embedded sub-package 630. In some embodiments, upon mounting the solder bumps 650 on the base board 601, the base thermal interface material layer 602 is in thermal contact with a plurality of semiconductor dice 637 of the embedded sub-package 630 and the base board 601. Therefore, heat generated by a plurality of semiconductor dice 637 may be transferred to the external of the base board 601 efficiently.

Referring to FIG. 7, compared with FIG. 6, a semiconductor package 700 further includes a top thermal interface material layer 703 on a plurality of semiconductor dice 720. Also, the semiconductor package 700 includes a top heat spreader 704, which can be disposed on the top thermal interface material layer 703 for direct heat dissipation of the plurality of semiconductor dice 720.

The discussion herein included numerous illustrative figures that showed various portions of a semiconductor package and method for forming a semiconductor package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a package substrate having a front side and a back side;
a first plurality of semiconductor dice disposed on the front side of the package substrate and electrically coupled to the package substrate;
an embedded sub-package disposed on the back side of the package substrate, the embedded sub-package comprising:
a sub-package substrate having a front side and a back side, wherein the front side of the sub-package substrate is attached to the back side of the package substrate and electrically coupled to the package substrate;
an interconnection layer attached to the back side of the sub-package substrate and electrically coupled to the sub-package substrate; wherein the interconnection layer comprises a second plurality of vertical interconnection portions and at least one horizontal interconnection portion; and
a second plurality of semiconductor dice disposed on the back side of the sub-package substrate through the interconnection layer, wherein each of the second plurality of semiconductor dice is electrically coupled to the sub-package substrate through at least one of the second plurality of vertical interconnection portions, and at least two of the second plurality of semiconductor dice are further electrically coupled to each other through the at least one horizontal interconnection portion, such that the first plurality of semiconductor dice are electrically coupled to each other through the embedded sub-package; and
a first plurality of vertical interconnection portions disposed on the back side of the package substrate and in parallel with the embedded sub-package, wherein each of the first plurality of semiconductor dice is electrically coupled to one of the first plurality of vertical interconnection portions; and
solder bumps attached to the first plurality of vertical interconnection portions.

2. The semiconductor package of claim 1, wherein each of the first plurality of vertical interconnection portions comprises at least one conductive via or at least one conductive pillar.

3. The semiconductor package of claim 1, further comprising: an interconnection portion heat spreader in thermal contact with the at least one horizontal interconnection portion.

4. The semiconductor package of claim 3, wherein the interconnection portion heat spreader comprises thermal conductive vias embedded in the sub-package substrate and the package substrate.

5. The semiconductor package of claim 1, wherein both the embedded sub-package and the first plurality of vertical interconnection portions are modularly preformed.

6. The semiconductor package of claim 1, further comprising: a base board, wherein the solder bumps are mounted on the base board; and
a base thermal interface material layer between the base board and the embedded sub-package, wherein the base thermal interface material layer is in thermal contact with the second plurality of semiconductor dice.

7. The semiconductor package of claim 6, further comprising:
a top thermal interface material layer on the first plurality of semiconductor dice; and
a top heat spreader disposed on the top thermal interface material layer.

8. A method for forming a semiconductor package, comprising:
providing a first plurality of semiconductor dice and a second plurality of semiconductor dice;
forming an embedded sub-package, comprising:
forming a second plurality of vertical interconnection portions on and electrically coupled to the second plurality of semiconductor dice;
attaching at least one horizontal interconnection portion on the second plurality of semiconductor dice, wherein at least two of the second plurality of semiconductor dice are electrically connected to each other via the at least one horizontal interconnection portion;
molding the second plurality of semiconductor dice, the second plurality of vertical interconnection portions and the at least one horizontal interconnection portion;
forming a sub-package substrate on the second plurality of semiconductor dice, the second plurality of vertical interconnection portions and the at least one horizontal interconnection portion, wherein the second plurality of vertical interconnection portions is electrically coupled to the sub-package substrate, wherein each of the second plurality of semiconductor dice is electrically coupled to the sub-package substrate through at least one of the second plurality of vertical interconnection portions;
forming a first plurality of vertical interconnection portions;
molding the embedded sub-package and the first plurality of vertical interconnection portions, wherein the first plurality of vertical interconnection portions is in parallel with the embedded sub-package;
attaching solder bumps, such that the solder bumps are electrically coupled to the first plurality of vertical interconnection portions;
forming a package substrate on the embedded sub-package and the first plurality of vertical interconnection portions, wherein the package substrate comprises a front side and a back side, wherein the first plurality of vertical interconnection portions and the sub-package substrate of the embedded sub-package are attached to and electrically coupled to the back side of the package substrate; and
disposing the first plurality of semiconductor dice on the front side of the package substrate, wherein the first plurality of semiconductor dice is electrically coupled to the package substrate, wherein the first plurality of semiconductor dice is electrically coupled to each other through the embedded sub-package, wherein each of the first plurality of semiconductor dice is electrically coupled to one of the first plurality of vertical interconnection portions.

9. The method of claim 8, wherein forming a first plurality of vertical interconnection portions comprises:
molding multiple conductive pillars;
forming a redistribution layer on the multiple conductive pillars, wherein the multiple conductive pillars are electrically connected to the redistribution layer;
performing singulation to the multiple conductive pillars to obtain a first plurality of vertical interconnection portions.

10. The method of claim 8, wherein forming a first plurality of vertical interconnection portions comprises:
forming multiple vias in a dielectric layer;
filling a conductive material in the multiple vias to form multiple conductive vias;
forming a redistribution layer on the multiple conductive vias, wherein the multiple conductive vias are electrically connected to the redistribution layer;
performing singulation to the multiple conductive vias to obtain a first plurality of vertical interconnection portions.

11. The method of claim 8, further comprising: forming an interconnection portion heat spreader in thermal contact with the at least one horizontal interconnection portion.

12. The method of claim 11, wherein forming an interconnection portion heat spreader comprises forming thermal conductive vias embedded in the sub-package substrate and the package substrate.

13. The method of claim 8, further comprising:
providing a base board;
forming a base thermal interface material layer beneath the embedded sub-package;
mounting the solder bumps on the base board, wherein the base thermal interface material layer is in thermal contact with the second plurality of semiconductor dice.

14. The method of claim 13, further comprising:
forming a top thermal interface material layer on the first plurality of semiconductor dice;
disposing a top heat spreader on the top thermal interface material layer.
